(19) United States
(12) Patent Application Publication
(10) Pub. No.: US 2024/0204532 A1
(43) Pub. Date: Jun. 20, 2024

(54) GRID-CONNECTED TYPE RENEWABLE ENERGY POWER GENERATION SYSTEM AND OPERATION METHOD THEREOF

(71) Applicant: SINAENG CO.,LTD., Gyeonggi-do (KR)

(72) Inventors: Byong Hee KANG, Seoul (KR); Hyung Kook KIM, Gyeonggi-do (KR); Young Ho SEO, Gyeonggi-do (KR)

(21) Appl. No.: 18/555,704

(22) PCT Filed: May 24, 2022
(86) PCT No.: PCT/KR2022/007362

§ 371 Date: Oct. 16, 2023

(30) Foreign Application Priority Data
Jun. 1, 2021 (KR) 10-2021-0071152

(51) Int. Cl. H02J 3/38; H02J 3/00; H03K 17/082; H03K 17/51; H03K 17/56

(52) U.S. Cl. CPC H02J 3/381; H02J 3/001; H03K 17/0824; H03K 17/56; H02J 2203/10; H02J 2300/20; H03K 2017/515

(57) ABSTRACT

The present invention relates to a grid-connected type renewable energy power generation system comprising: a power generation unit for producing and outputting electric energy; an energy storage unit for storing electric energy produced and output from the power generation unit; a power conversion unit for supplying electric energy output from the power generation unit of the energy storage unit to a load or a gird; and a switching unit configured by a switching semiconductor for electric power, the switching semiconductor being connected between the power conversion unit and the grid and enabling active switching control, wherein when energy is independently supplied to the load by the power conversion unit or an abnormality occurs in the power conversion unit, an off signal is applied to a gate of the switching semiconductor enabling active switching control of the switching unit.

### BACKGROUND

### Field

The present invention relates to a grid-connected type renewable energy power generation system and an operation method thereof, and particularly, to a grid-connected type renewable energy power generation system capable of independently operating regardless of the phase of a voltage or current during stable high-speed operation, or independently and immediately interrupting connection to grid in the event of occurrence of abnormality, and an operation method thereof.

### Related Art

A grid-connected renewable energy power generation system can also be used as a power supply for supplying power to very sensitive loads. Power is normally supplied through a grid for stability of power supplied, the grid-connected renewable energy power generation system independently operates to supply power to a load, and in a case where an abnormality occurs in the power generation system or repair is required, circuit connection between the renewable energy power generation system and the grid needs to be interrupted.

Power used in semiconductor manufacturing processes, bio and chemical processes, and the like needs to be supplied to important loads at all times without interruption to maintain the stability of power supplied to the entire process.

A conventional grid-connected renewable energy power generation system may use a thyristor which is also called a silicon controlled rectifier (SCR) switch for circuit connection with the grid or disconnection from the grid. In such an SCR switch or thyristor, commutation is inevitable, and thus commutation to the grid needs to be terminated for an interruption operation of the SCR switch or thyristor for connecting the output of the renewable energy power generation system to the grid.

If the interruption operation is not completed for 8 to 16 ms in order to terminate commutation from the renewable energy power generation system to the grid, not only the renewable energy power generation system but also the grid are affected, causing significant damage to all connected power lines.

Korean Patent No. 10-1020789 relates to a grid-connected hybrid solar power generation system having an uninterruptible function, which includes a PV converter that supplies generated power of a solar cell 700, a battery charging-discharging converter that charges and discharges a battery, and an inverter that converts direct-current power into alternating-current power and supplies it to a system and a load in order to have an uninterruptible function of interrupting grid connection and sending the generated power of the solar cell to the load in the event of power outage, in which the converters and the inverter are controlled by a controller, a charging-discharging relay opens to separate the battery charging-discharging converter from a DC bus when the output of the inverter/rectifier is connected to the system under the control of the controller, and in other cases, short-circuits to connect the battery charging-discharging converter to the DC bus. Meanwhile, a gird connection relay opens to separate the inverter/rectifier from the grid in the event of power outage in the grid or when power from the battery is sent to the DC bus, and in other cases, short-circuits to connect the inverter/rectifier to the grid. However, the grid connection relay requires a predetermined time for the interruption operation as a relay or a magnetic contactor (MC) which is a mechanical switch, affecting not only the solar power generation system but also the grid and causing significant damage to the entire power lines.

Korean Patent No. 10-2039888 relates to a power transfer switch, in which a first switching element and a second switching element are turned on or off by a driver controller such that power from an uninterruptible power supply device or reserve power is supplied to semiconductor manufacturing process equipment in order to supply stable reserve power in an uninterrupted manner when the output power of the uninterruptible power supply device supplied to the semiconductor manufacturing process equipment is unstable. However, the first switching element and the second switching element are merely components for connecting the uninterruptible power supply device and external reserve power to loads, and when an abnormality has occurred in a renewable energy power generation system or repair is required, the configuration for interrupting circuit connection between the renewable energy power generation system and the grid is not specifically indicated.

Korean Patent No. 10-2126209 relates to an overcurrent protection power transfer switch in which, even if short-circuit occurs in a part of semiconductor manufacturing process equipment, an SCR switch and a field effect transistor (FET) bidirectional switch of a second switching element are sequentially turned on such that a first switching element is turned off and the second switching element is turned on by a drive controller in order to supply stable reserve power to the remaining part of the semiconductor manufacturing process equipment in an uninterrupted manner. However, the first switching element and the second switching element are merely components for connecting the uninterruptible power supply device and external reserve power to loads, and when an abnormality occurs in a renewable energy power generation system or repair is required, the configuration for blocking circuit connection between the renewable energy power generation system and the grid is not specifically indicated.

### SUMMARY

The present invention is devised to solve the above problems, and an object of the present invention is to enable independent and immediate circuit interruption to minimize damage without affecting a grid-connected renewable energy power generation system and a grid.

Another object of the present invention is to allow a switching unit that connects the output of an internal inverter of the grid-connected renewable energy power generation system to the grid to be independently turned on/off regardless of commutation within a short period of time, thereby improving the reliability of the grid-connected renewable energy power generation system.

Another purpose of the present invention is to achieve stable high-speed operation and rapid switching regardless of the phase of a voltage or current to prevent the grid-connected renewable energy power generation system and the grid from being damaged.

Another object of the present invention is to connect the grid-connected renewable energy power generation system to the grid and disconnect the grid-connected renewable energy power generation system from the grid independently and rapidly without relying on a voltage or current sensor regardless of the phase of a voltage or current.

The objects to be accomplished by the present invention are not limited to the above objects, and other objects that are not specified may be additionally considered within the scope that can be easily inferred from the following detailed description and effects thereof.

To accomplish the above-described objects, the present invention includes the following configurations.

A grid-connected renewable energy power generation system of the present invention includes: a power generator configured to produce and output electric energy; an energy storage system configured to store electric energy produced and output from the power generator; a power conditioning system configured to supply electric energy output from the power generator or the energy storage system to a load or a grid; and a switching unit including a power switching semiconductor capable of active switching control connected between the power conditioning system and the grid, wherein energy is supplied to the load independently by the power conditioning system, or in a case where an abnormality occurs in the power conditioning system, an off signal is applied to a gate of the power switching semiconductor capable of active switching control of the switching unit.

The present invention is characterized in that the switching unit further includes an SCR switch, and the SCR switch is connected in parallel with the power switching semiconductor capable of active switching control.

The present invention is characterized in that energy is supplied to the load independently by the power conditioning system, an off signal is applied to the gate of the power switching semiconductor capable of active switching control of the switching unit such that connection between the power conditioning system and the grid is interrupted and thus independent supply of energy to the load by the power conditioning system is stopped in a case where an abnormality occurs in the power conditioning system, or the SCR switch of the switching unit is turned on first and then the power switching semiconductor capable of active switching control of the switching unit is sequentially turned on such that energy output from the power generator or the energy storage system is supplied to the gird in a case where the power conditioning system normally operates.

The present invention is characterized in that the switching unit further includes a mechanical switch, the mechanical switch is connected in parallel with the SCR switch of the switching unit and the power switching semiconductor capable of active switching control, and energy is supplied to the load independently by the power conditioning system, an off signal is applied to the gate of the power switching semiconductor capable of active switching control of the switching unit such that connection between the power conditioning system and the grid is interrupted and thus independent supply of energy to the load by the power conditioning system is stopped in a case where an abnormality occurs in the power conditioning system, or the SCR switch, the mechanical switch, and the power switching semiconductor capable of active switching control of the switching unit are sequentially turned on such that energy output from the power generator or the energy storage system is supplied to the gird in a case where the power conditioning system normally operates.

The present invention is characterized in that, after the SCR switch, the mechanical switch, and the power switching semiconductor capable of active switching control of the switching unit are sequentially turned on, the SCR switch and the mechanical switch are turned off and the power switching semiconductor capable of active switching control is kept turned on.

The present invention is characterized in that the mechanical switch is a relay or a magnetic contactor (MC).

Furthermore, an operation method of a grid-connected renewable energy power generation system performing connection and disconnection between a power conditioning system and a grid by a switching unit including a power switching semiconductor capable or active switching control, an SCR switch, and a mechanical switch connected in parallel of the present invention includes: a first step S100 of first turning on the SCR switch of the switching unit and then sequentially turning on the mechanical switch in a case where connection between the power conditioning system and the grid is recovered; a second step S200 of turning on the power switching semiconductor capable of active switching control in a case where current flowing through the SCR switch or the mechanical switch is within an allowable current range after the SCR switch and the mechanical switch of the switching unit are sequentially turned on; and a third step S300 of turning off the SCR switch and the mechanical switch and keeping the power switching semiconductor capable of active switching control turned on.

The present invention may be a computer program stored in a storage medium to execute the operation method of a grid-connected renewable energy power generation system.

### Advantageous Effects

An effect of the present invention is to enable independent and immediate circuit interruption to minimize damage without affecting the grid-connected renewable energy power generation system and the grid.

Another effect of the present invention is to allow a switching unit that connects the output of an internal inverter of the grid-connected renewable energy power generation system to the grid to be independently turned on/off regardless of commutation within a short period of time, thereby improving the reliability of the grid-connected renewable energy power generation system.

Another effect of the present invention is to achieve stable high-speed operation and rapid switching regardless of the phase of a voltage or current to prevent the grid-connected renewable energy power generation system and the grid from being damaged.

Another effect of the present invention is to connect the grid-connected renewable energy power generation system to the grid and disconnect the grid-connected renewable energy power generation system from the grid independently and rapidly without relying on a voltage or current sensor regardless of the phase of a voltage or current.

The effects obtained by the present invention are not limited to the above effects, and other effects that are not specified may be additionally considered within the scope that can be easily inferred from the following detailed description and effects thereof.

### BRIEF DESCRIPTION OF THE DRAWINGS

FIG. 1 shows an internal configuration of a conventional grid-connected renewable energy power generation system.

FIG. 2 shows an embodiment of a grid-connected renewable energy power generation system of the present invention.

FIG. 3 shows another embodiment of the grid-connected renewable energy power generation system of the present invention.

FIG. 4 shows another embodiment of the grid-connected renewable energy power generation system of the present invention.

FIG. 5 shows another embodiment of the grid-connected renewable energy power generation system of the present invention.

FIG. 6 shows another embodiment of the grid-connected renewable energy power generation system of the present invention.

FIG. 7 shows another embodiment of the grid-connected renewable energy power generation system of the present invention.

### DESCRIPTION OF EXEMPLARY EMBODIMENTS

Hereinafter, the overall configuration and operation according to preferred embodiments of the present invention will be described. These embodiments are illustrative and do not limit the configuration and operation of the present invention, and other configurations and operations that are not explicitly shown in the embodiments can also be regarded as the technical idea of the present invention if they are easily understood by those skilled in the art to which the present invention pertains through embodiments below.

A grid-connected renewable energy power generation system can also be used as a power supply for supplying power to very sensitive loads. Power is normally supplied through the grid for stability of power supplied, and the grid-connected renewable energy power generation system independently operates to supply power to loads, and when an abnormality occurs in the power generation system or repair is required, circuit connection between the renewable energy power generation system and the grid needs to be immediately interrupted.

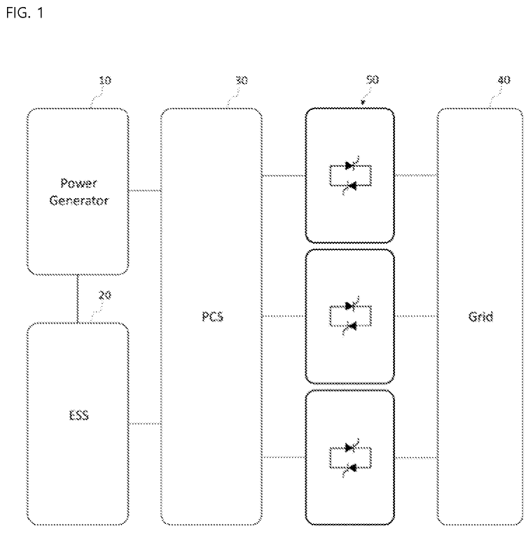

FIG. 1 shows an internal configuration of a conventional grid-connected renewable energy power generation system.

Referring to FIG. 1, the conventional grid-connected renewable energy power generation system includes a power generator 10 that produces and outputs electric energy, and an energy storage system (ESS) 20 that stores the electric energy produced and output from the power generation unit 10, a power conditioning system (PCS) 30 that supplies the electric energy output from the power generation unit 10 or the ESS 20 to a load or a grid 40, and a switching unit 50 including an SCR switch connected between the PCS 30 and the grid 40.

The PCS 30 operates independently to supply power to the load, or needs to interrupt circuit connection between the renewable energy power generation system and the grid in a case where an abnormality occurs in the renewable energy power generation system or repair is required.

Commutation is inevitable in a switching circuit using a thyristor which is also called a silicon controlled rectifier (SCR) switch, and thus in order to interrupt connection between the PCS 30 and the grid 40, a method of applying input through a voltage sensor or a current sensor or setting a certain period of time in which the SCR switch is turned off is adopted.

However, such a method may cause overcurrent during commutation due to calculation errors caused by an offset or the like. To prevent this, an SCR switch off time is maintained for more than half a cycle to prevent damage by overcurrent. However, power applied to a load is off for 8 ms or longer, and thus a problem of shutdown of a load system in the case of a load sensitive to power may occur.

In addition, in order to interrupt connection between the renewable energy power generation system and the grid, commutation from the PCS 30 to the grid 40 needs to be terminated first. Accordingly, the circuit connection cannot be interrupted for 8 ms to 16 ms, which has a negative impact not only on the renewable energy power generation system but also on the grid, causing significant damage to all connected power lines.

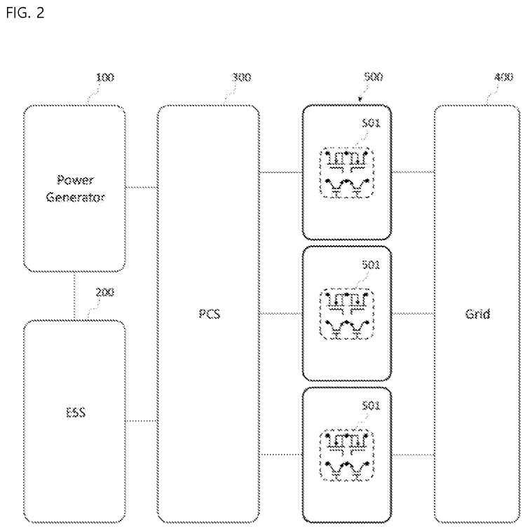

FIG. 2 shows an embodiment of a grid-connected renewable energy power generation system of the present invention.

Referring to FIG. 2, the grid-connected renewable energy power generation system, which is an embodiment of the present invention, includes a power generator 100 that produces and outputs electric energy, an energy storage system (ESS) 200 that stores the electric energy produced and output from the power generator 100, a power conditioning system (PCS) 300 that supplies the electric energy output from the power generator 100 or the ESS 200 to a load or a grid 400, and a switching unit 500 including a power switching semiconductor 501 capable of active switching control connected between the PCS 300 and the grid 400.

The power generator 100 produces electric energy from renewable energy such as solar power and wind power, and the PCS 300 may supply the electric energy produced and output from the power generator 100 to the grid 400 or supply electric energy output from the ESS 200 to a load or the grid 400 and may include an inverter provided thereinside to convert the phase and frequency of the output power.

The switching unit 500 includes a power switching semiconductor 501 capable of active switching control, and the power switching semiconductor 501 capable of active switching control may be a metal oxide semiconductor field effect transistor (MOSFET) bidirectional switch or an insulated gate bipolar transistor (IGBT) bidirectional switch capable of “active” switching control without an additional circuit for ON/OFF.

The power semiconductor 501 capable of active switching control can operate having a response time of several us or less only by applying an on signal or an off signal to the gate thereof unlike the SCR switch capable of “passive” switching using an additional circuit for OFF.

The power switching semiconductor 501 capable of active switching control can perform independent and immediate circuit interruption, and thus can prevent adverse effects on the renewable energy generation system and the grid 40. In addition, when a plurality of renewable energy power generation systems is connected to the grid 400 and thus delay occurs in connection and disconnection therebetween, the renewable energy power generation systems may cause significant damage in the grid 400 even if each renewable energy power generation system has a small capacity. However, the present invention can minimize such cumulative damage because connection and disconnection between the renewable energy generation system and the grid 400 are immediately performed.

The operation of the switching unit 500 may be performed by a control unit, and illustration of the control unit is omitted.

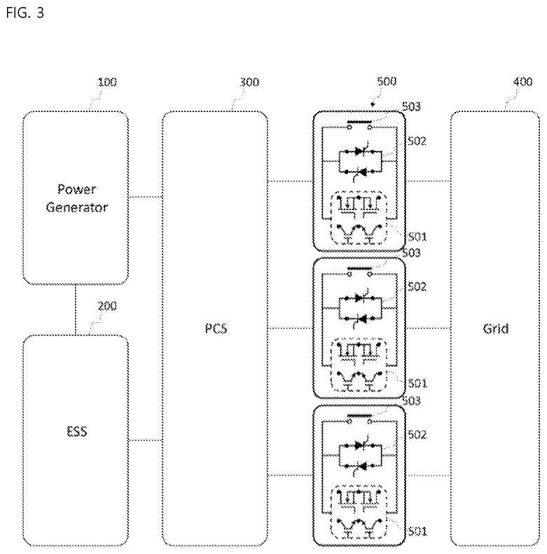

FIG. 3 shows another embodiment of the grid-connected renewable energy power generation system of the present invention.

Referring to FIG. 3, the grid-connected renewable energy power generation system, which is another embodiment of the present invention, includes the power generator 100 that produces and outputs electric energy, the ESS (energy storage system) 200 that stores the electric energy produced and output from the power generator 100, the power conditioning system (PCS) 300 that supplies the electric energy output from the power generator 100 or the ESS 200 to a load or the grid 400, and the switching unit 500 connected between the PCS 300 and the grid 400.

In particular, as compared to the configuration shown in FIG. 2, the switching unit 500 further includes an SCR switching 502 and a relay or magnetic contactor (MC) which is a mechanical switch, which are connected in parallel with the power switching semiconductor 501 capable of active switching control.

Before operation of the PCS 300, the SCR switch 502 of the switching unit 500 is turned on first or the relay or magnetic contactor (MC) 503 is turned on, and then the power switching semiconductor 501 capable of active switching control is sequentially turned on.

In case of generation of overcurrent from the grid 400, among the relay or magnetic contactor (MC) 503, the SCR switch 502, and the power switching semiconductor 501 capable of active switching control of the switching unit 500, the SCR switch 502 having high withstand capacity is turned on first, or the relay or magnetic contactor (MC) 501 is turned on, and then the power switching semiconductor 501 capable of active switching control is sequentially turned on in a case where current flowing therethrough is less than an allowable current.

The SCR switch 502 may be turned on first in consideration of the high switching speed and high withstand capacity thereof, and then the power switching semiconductor 501 capable of active switching control which has a high switching speed but has low withstand capacity may be turned on. Since the PCS 300 is not yet operated, the relay or magnetic contactor (MC) 503 may be turned on in consideration of the low switching speed and high withstand capacity thereof, and then the power switching semiconductor 501 capable of active switching control which has a high switching speed but has low withstand capacity may be turned on.

When the power switching semiconductor 501 capable of active switching control is sequentially turned on, the SCR switch 502 and the relay or magnetic contactor (MC) 503 are turned off and the power switching semiconductor 501 capable of active switching control is kept turned on such that the PCS 300 independently operates to supply power to the load, or prepares for a case in which an abnormality occurs in the renewable energy power generation system or repair is required.

Accordingly, the PCS 300 can operate independently to supply power to the load, or turn off the power switching semiconductor 501 capable of active switching control to immediately interrupt circuit connection between the renewable energy power generation system and the grid 400 in a case where an abnormality occurs in the renewable energy power generation system or repair is required.

For circuit connection between the renewable energy power generation system and the grid 400 after interruption of circuit connection between the renewable energy power generation system and the grid 400, the SCR switch 502 of the switching unit 500 is turned on first, and then the relay or magnetic contactor (MC) 503 and the power switching semiconductor 501 capable of active switching control are sequentially turned on to achieve circuit connection between the renewable energy power generation system and the grid 400.

Accordingly, the SCR switch 502 having high withstand capacity is turn on first between the SCR switch 502 and the power switching semiconductor 501 capable of active switching control of the switching unit 500 in case of generation of short-circuit current from the load, and then the relay or magnetic contactor (MC) 503 having higher withstand capacity is also turned on.

The SCR switch 502 is turned on first in consideration of the high switching speed and withstand capacity, and then the relay or magnetic contactor (MC) 503 which has a low switching speed but has high withstand capacity is turned on, and finally the power switching semiconductor 501 capable of active switching control which has a high switching speed but has low withstand capacity is turned on.

Of course, in a case where the current flowing through the SCR switch 502 and the relay or magnetic contactor (MC) 503 is less than the allowable current, the power switching semiconductor 501 capable of active switching control is turned on.

In a case where overcurrent occurs from the grid 400, damage can be prevented by first turning on the SCR switch 502 having high withstand capacity, and then the relay or magnetic contactor (MC) 503 is also turned on immediately to further prevent damage even when there is a risk of overcurrent or overcurrent is detected.

Thereafter, when the power switching semiconductor 501 capable of active switching control is sequentially turned on in a case where the current flowing through the relay or magnetic contactor (MC) 503 is less than the allowable current, the SCR switch 502 and the relay or magnetic contactor (MC) 503 are turned off and the power switching semiconductor 501 capable of active switching control is kept turned on.

The operation of the switching unit 500 may be performed by the control unit, and illustration of the control unit is omitted.

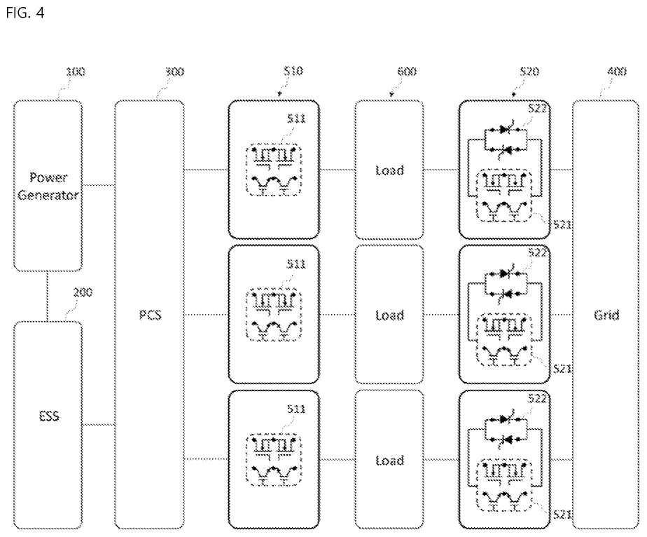

FIG. 4 shows another embodiment of the grid-connected renewable energy power generation system of the present invention.

Referring to FIG. 4, the grid-connected renewable energy power generation system, which is another embodiment of the present invention, includes the power generator 100 that produces and outputs electric energy, the ESS (energy storage system) 200 that stores the electric energy produced and output from the power generator 100, the power conditioning system (PCS) 300 that supplies the electric energy output from the power generator 100 or the ESS 200 to a load or the grid 400, a load 600 that receives the power from the PCS 300 or the grid 400, a first switch 510 that performs circuit connection and circuit connection interruption between the PCS 300 and the load 600, and a second switch 520 that performs circuit connection and circuit connection interruption between the grid 400 and the load 600

Here, illustration of the switching unit 500 connected between the PCS 300 and the grid 400 is omitted.

In a case where an abnormality occurs in the PCS 300 while power is being supplied from the PCS 300 to the load 600, an off signal is applied to the gate of a power switching semiconductor 511 capable of active switching control of the first switch 510, and at the same time, an SCR switch 522 of the second switch 520 is turned on first, and then a power switching semiconductor 521 capable of active switching control is sequentially turned on. In this manner, in a case where power is supplied from the grid 400 to the load and thus overcurrent occurs from the grid 400, damage can be prevented by first turning on the SCR switch 522 having high withstand capacity.

When the power switching semiconductor 521 capable of active switching control is sequentially turned on in a case where the current flowing through the SCR switch 522 is less than the allowable current, the SCR switch 522 is turned off and the power switching semiconductor 521 capable of active switching control is kept turned on to prepare for the case where the PCS 300 returns to the normal operation.

The first switch 510 and the second switch 520 include power switching semiconductors 511 and 521 capable of active switching control, and the power switching semiconductors 511 and 521 capable of active switching control may be MOSFET bidirectional switches or IGBT bidirectional switches capable of “active” switching control without additional circuit for ON/OFF.

The power semiconductors 511 and 521 capable of active switching control can operate having a response time of several us or less only by applying an on signal or an off signal to the gate thereof unlike the SCR switch capable of “passive” switching using an additional circuit for OFF.

The operations of the first switch 510 and the second switch 520 may be performed by the control unit, and illustration of the control unit is omitted.

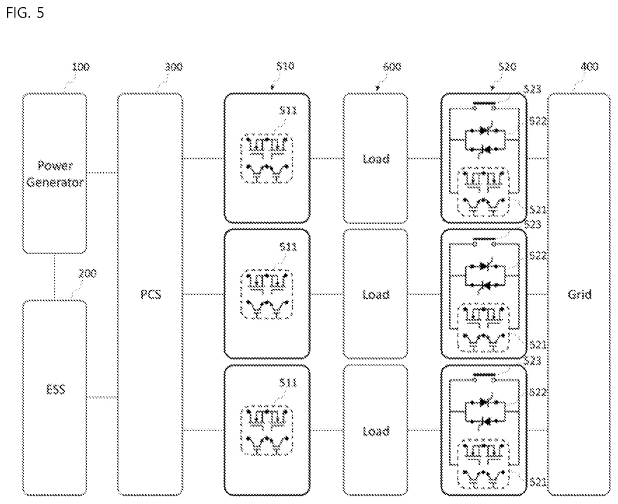

FIG. 5 shows another embodiment of the grid-connected renewable energy power generation system of the present invention.

Referring to FIG. 5, as compared to the embodiment of the present invention shown in FIG. 4, the second switch 520 further includes a relay or magnetic contactor (MC) 523 connected in parallel.

In a case where an abnormality occurs in the PCS 300 while power is being supplied from the PCS 300 to the load 600, an off signal is applied to the gate of the power switching semiconductor 511 capable of active switching control of the first switch 510, and at the same time, the SCR switch 522 of the second switch 520 is turned on first, and then the relay or magnetic contactor (MC) 523 and the power switching semiconductors 521 capable of active switching control are sequentially turned on such that power is supplied from the grid 400 to the load.

When overcurrent occurs from the grid 400, damage can be prevented by first turning on the SCR switch 522 having high withstand capacity, and then the relay or magnetic contactor (MC) 523 is also turned on immediately to further prevent damage even when there is a risk of overcurrent or overcurrent is detected.

Thereafter, when the power switching semiconductor 521 capable of active switching control is sequentially turned on in a case where the current flowing through the relay or magnetic contactor (MC) 523 is less than the allowable current, the SCR switch 522 and the relay or magnetic contactor (MC) 523 are turned off and the power switching semiconductor 501 capable of active switching control is kept turned on to prepare for the case where the PCS 300 returns to the normal operation.

The operations of the first switch 510 and the second switch 520 may be performed by the control unit, and illustration of the control unit is omitted.

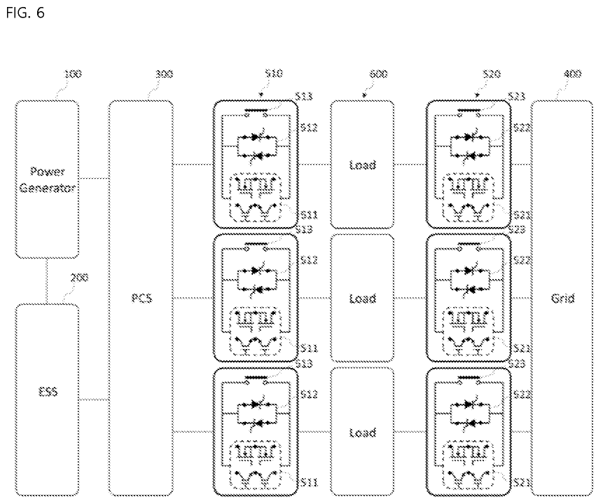

FIG. 6 shows another embodiment of the grid-connected renewable energy power generation system of the present invention.

Referring to FIG. 6, as compared to the embodiment of the present invention shown in FIG. 5, the first switch 510 further includes an SCR switch 512 and a relay or magnetic contactor (MC) 513 connected in parallel.

In a case where the PCS 300 returns to the normal operation while power is being supplied from the grid 400 to the load 600, an off signal is applied to the gate of the power switching semiconductor 521 capable of active switching control of the second switch 520, and at the same time, the SCR switch 512 of the first switch 510 is turned on first, and then the relay or magnetic contactor (MC) 513 and the power switching semiconductors 511 capable of active switching control are sequentially turned on such that power is immediately supplied from the PCS 300 to the load 600.

When overcurrent occurs from the PCS 300, damage can be prevented by first turning on the SCR switch 512 having high withstand capacity, and then the relay or magnetic contactor (MC) 523 is immediately turned on to further prevent damage even when there is a risk of overcurrent or overcurrent is detected.

Thereafter, when the power switching semiconductor 511 capable of active switching control is sequentially turned on in a case where the current flowing through the relay or magnetic contactor (MC) 513 is less than the allowable current, the SCR switch 512 and the relay or magnetic contactor (MC) 513 are turned off and the power switching semiconductor 511 capable of active switching control is kept turned on to prepare for the case where the PCS 300 has an abnormality.

The operations of the first switch 510 and the second switch 520 may be performed by the control unit, and illustration of the control unit is omitted.

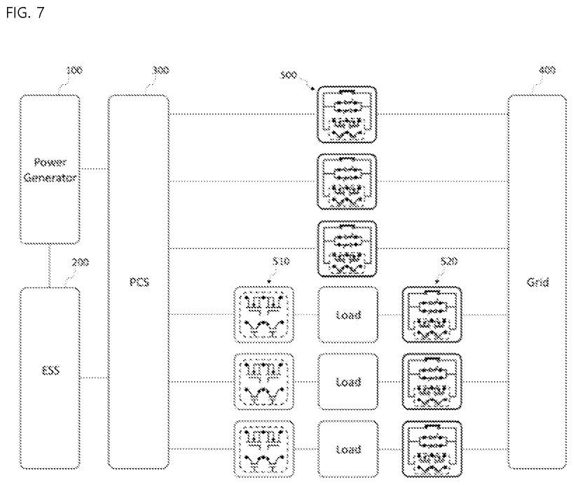

FIG. 7 shows another embodiment of the grid-connected renewable energy power generation system of the present invention.

Referring to FIG. 7, which shows an embodiment of the present invention as shown in FIGS. 3 and 5 as a whole, includes the switching unit 500 connected between the PCS 300 and the grid 400, the first switch 510 that performs circuit connection and circuit connection interruption between the PCS 300 and the load 600, and the second switch 520 that performs circuit connection and circuit connection interruption between the grid 400 and the load 600.

The operation method of the switching unit 500, the first switch 510, and the second switch 520 is the same as previously described, the operations of the switching unit 500, the first switch 510, and the second switch 520 may be performed by the control unit, and illustration of the control unit is omitted.

The present invention can prevent the system from being damaged due to abnormalities in transfer time and transfer time control between the grid-connected renewable energy power generation system, the grid, and a load, minimize the configuration for heat dissipation by connecting SCR switches, which are connected in parallel in the switching unit, the first switch, and the second switch connected between the grid-connected renewable energy power generation system and the grid, between the grid-connected renewable energy power generation system and the load, and between the grid and the load, for a very short period of time, and allow a user to turn on/off the switching unit, the first switch, and the second switch regardless of commutation since connection/disconnection by the switching unit, the first switch, and the second switch can be independently performed regardless of the magnitude or phase of current to further improve the reliability of the grid-connected renewable energy power generation system.

Furthermore, since the switching unit, the first switch, and the second switch of the present invention have a parallel structure, they can be applied to the existing grid-connected renewable energy power generation systems without modifying the systems. Although switching is possible in conventional grid-connected renewable energy power generation systems only by observing commutation, the grid-connected renewable energy power generation system of the present invention allows the user to freely perform switching at a desired point in time without observing commutation, thereby further improving the reliability of the product.

In addition, the method of operating the grid-connected renewable energy power generation system of the present invention can be implemented as a computer program, and each component of the present invention can be implemented as hardware or software, and thus it can be implemented as software executed in one piece of hardware or an individual piece of hardware. Additionally, the method of operating the grid-connected renewable energy power generation system of the present invention may be implemented be being stored as a computer program in a recording medium.

### REFERENCE SIGNS LIST

10, 100: Power generator
20, 200: Energy Storage System (ESS)
30, 300: Power conditioning system (PCS)
40, 400: Grid
50, 500: Switching unit
501, 511, 521: Power switching semiconductor capable of active switching control
502, 512, 522: SCR switch
503, 513, 523: Relay or magnetic contactor (MC)
510: First switch
520: Second switch
600: load

1. A grid-connected renewable energy power generation system comprising:
a power generator configured to produce and output electric energy;
an energy storage system configured to store electric energy produced and output from the power generator;
a power conditioning system configured to supply electric energy output from the power generator or the energy storage system to a load or a grid; and
a switching unit including a power switching semiconductor capable of active switching control connected between the power conditioning system and the grid,
wherein energy is supplied to the load independently by the power conditioning system, or in a case where an abnormality occurs in the power conditioning system, an off signal is applied to a gate of the power switching semiconductor capable of active switching control of the switching unit.

2. The grid-connected renewable energy power generation system of claim 1, wherein the switching unit further includes an SCR switch, and
the SCR switch is connected in parallel with the power switching semiconductor capable of active switching control.

3. The grid-connected renewable energy power generation system of claim 2, wherein energy is supplied to the load independently by the power conditioning system, an off signal is applied to the gate of the power switching semiconductor capable of active switching control of the switching unit such that connection between the power conditioning system and the grid is interrupted and thus independent supply of energy to the load by the power conditioning system is stopped in a case where an abnormality occurs in the power conditioning system, or the SCR switch of the switching unit is turned on first and then the power switching semiconductor capable of active switching control of the switching unit is sequentially turned on such that energy output from the power generator or the energy storage system is supplied to the gird in a case where the power conditioning system normally operates.

4. The grid-connected renewable energy power generation system of claim 2, wherein the switching unit further includes a mechanical switch,
the mechanical switch is connected in parallel with the SCR switch of the switching unit and the power switching semiconductor capable of active switching control, and
energy is supplied to the load independently by the power conditioning system, an off signal is applied to the gate of the power switching semiconductor capable of active switching control of the switching unit such that connection between the power conditioning system and the grid is interrupted and thus independent supply of energy to the load by the power conditioning system is stopped in a case where an abnormality occurs in the power conditioning system, or the SCR switch, the mechanical switch, and the power switching semiconductor capable of active switching control of the switching unit are sequentially turned on such that energy output from the power generator or the energy storage system is supplied to the gird in a case where the power conditioning system normally operates.

5. The grid-connected renewable energy power generation system of claim 3, wherein, after the SCR switch, the mechanical switch, and the power switching semiconductor capable of active switching control of the switching unit are sequentially turned on, the SCR switch and the mechanical switch are turned off and the power switching semiconductor capable of active switching control is kept turned on.

6. The grid-connected renewable energy power generation system of claim 4, wherein the mechanical switch is a relay or a magnetic contactor (MC).

7. An operation method of a grid-connected renewable energy power generation system performing connection and disconnection between a power conditioning system and a grid by a switching unit including a power switching semiconductor capable or active switching control, an SCR switch, and a mechanical switch connected in parallel, the operating method comprising:
a first step S100 of first turning on the SCR switch of the switching unit and then sequentially turning on the mechanical switch in a case where connection between the power conditioning system and the grid is recovered;
a second step S200 of turning on the power switching semiconductor capable of active switching control in a case where current flowing through the SCR switch or the mechanical switch is within an allowable current range after the SCR switch and the mechanical switch of the switching unit are sequentially turned on; and
a third step S300 of turning off the SCR switch and the mechanical switch and keeping the power switching semiconductor capable of active switching control turned on.

8. A computer program stored in a storage medium to execute the operation method of a grid-connected renewable energy power generation system of claim 7.
